(19) United States
(12) Patent Application Publication
(10) Pub. No.: US 2018/0366294 A1
(43) Pub. Date: Dec. 20, 2018

(54) ELECTRON BEAM APPARATUS, AND X-RAY GENERATION APPARATUS AND SCANNING ELECTRON MICROSCOPE EACH INCLUDING THE SAME

(71) Applicant: Shimadzu Corporation, Kyoto (JP)

(72) Inventor: Akihiro MIYAOKA, Kyoto (JP)

(73) Assignee: Shimadzu Corporation, Kyoto (JP)

(21) Appl. No.: 15/919,561

(22) Filed: Mar. 13, 2018

(30) Foreign Application Priority Data
Jun. 16, 2017 (JP) 2017-118599

(51) Int. Cl. H01J 3/07; H01J 37/075; H01J 35/14; H01J 3/02; H01J 37/12

(52) U.S. Cl. CPC H01J 3/07; H01J 37/075; H01J 35/14; H01J 37/28; H01J 37/12; H01J 2237/06308; H01J 3/024

(57) ABSTRACT

An electron beam apparatus includes: a cathode configured to emit electrons; an anode that is an electrode which forms an electric field such that an electron beam is formed by the electrons emitted from the cathode, and that is formed with a first hole through which the electron beam passes; an aperture member formed with an opening that shades a part of the electron beam which passes through the anode; and a convergence electrode that is an electrode which forms an electric field such that the electron beam which passes through the opening converges, and that is configured to include one single-hole electrode formed with a second hole through which the electron beam passes.

### FIELD

The present invention relates to an electron beam apparatus, and an X-ray generation apparatus and a scanning electron microscope each including the same.

### BACKGROUND

In an electron beam apparatus, which is used for a scanning electron microscope, an X-ray generation apparatus, or the like, an electro-magnetic lens and an electro-static lens are used as an electron lens which causes an electron beam to converge. Generally, it is easy to reduce a size of the electro-static lens, compared to the electro-magnetic lens. In a scanning electron microscope disclosed in Patent Literature 1, a size of the electron beam apparatus is reduced in such a way that an electron gun lens and an object lens are respectively used as the electro-static lens.

[Patent Literature 1] JP-A-6-111745

### SUMMARY

The electron beam apparatus is mounted on various machines including the X-ray generation apparatus and the scanning electron microscope. With such a background, it is desired to further reduce the size of the electron beam apparatus itself.

An object of the present invention is to provide a small-sized high-resolution electron beam apparatus, and an X-ray generation apparatus and a scanning electron microscope each including the same.

According to an aspect of the present invention, there is provided an electron beam apparatus including: a cathode configured to emit electrons; an anode that is an electrode which forms an electric field such that an electron beam is formed by the electrons emitted from the cathode, and that is formed with a first hole through which the electron beam passes; an aperture member formed with an opening that shields a part of the electron beam which passes through the anode; and a final-stage electron lens that is an electrode which forms an electric field such that the electron beam which passes through the opening converges, and that is configured to include one single-hole electrode formed with a second hole through which the electron beam passes.

According to the configuration, the final-stage electron lens, which forms the electric field such that the electron beam converges, includes one single-hole electrode. Therefore, it is possible to reduce a size compared to, for example, a case where the electron lens includes a plurality of single-hole electrodes like an einzel lens. Therefore, it is possible to reduce a size of the electron beam apparatus.

In addition, according to the configuration, the aperture member shields the electron beam at a peripheral part of the electron beam which has a bad converging property, only the central part of the electron beam which has a good converging property passes through the opening of the aperture member, and, thereafter, the electron beam converges by the final-stage electron lens. Therefore, it is possible to suppress degradation of resolution.

According to an example of the electron beam apparatus, an electric potential of the aperture member is the same as an electric potential of the single-hole electrode.

According to the configuration, it is not necessary to provide an insulation distance in order to prevent electric discharge between the single-hole electrode and the aperture member. Therefore, it is possible to reduce a distance between the single-hole electrode and the aperture member. Therefore, it is possible to reduce a size of the electron beam apparatus.

According to an example of the electron beam apparatus, as a method for applying the same electric potential, a first electrically-conducting member is further included in which the aperture member and the single-hole electrode are electrically conducted to each other in vacuum, and which is different from a wire configured to apply the electric potential.

According to the configuration, it is possible to apply the electric potential to both the single-hole electrode and the aperture member via one wire, with the result that it is possible to reduce the number of wires, and thus it is possible to simplify a configuration of the electron beam apparatus.

According to an example of the electron beam apparatus, an electric potential of the anode is the same as the electric potential of the aperture member.

According to the configuration, it is not necessary to provide an insulation distance in order to prevent the electric discharge between the anode and the aperture member. Therefore, it is possible to reduce the distance between the anode and the aperture member. Therefore, it is possible to reduce a size of the electron beam apparatus.

According to an example of the electron beam apparatus, as the method for applying the same electric potential, a second electrically-conducting member is included in which the anode and the aperture member are electrically conducted to each other in vacuum, and which is different from the wire configured to apply the electric potential.

According to the configuration, it is possible to apply the electric potential to both the anode and the aperture member via one wire, with the result that it is possible to reduce the number of wires, and thus it is possible to simplify the configuration of the electron beam apparatus.

According to an example of the electron beam apparatus, a distance between the aperture member and the single-hole electrode in a direction along an optical axis of the electron beam is longer than a radius of the second hole.

According to the configuration, it is possible to ignore an operation of the electro-static lens due to the aperture member. Therefore, it is possible to design an opening diameter of the aperture member without taking the operation of the lens into consideration.

According to an example of the electron beam apparatus, the cathode includes an emission surface which is a planar surface capable of emitting the electrons, and an area of the emission surface is larger than an opening area of the first hole.

According to the configuration, for example, compared to a case where the cathode is formed of pointed metal, it is not necessary to perform high-precision adjustment on a position of the cathode with respect to the first hole, and thus it is possible to easily construct the electron beam apparatus.

According to an example of the electron beam apparatus, the cathode is a thermionic electron emission type.

According to the configuration, for example, compared to a configuration which includes an electric field emission-type cathode, a degree of vacuum in the electron beam apparatus may be low. Therefore, it is possible to reduce a size of a vacuum pump used to vacuate an inside of the electron beam apparatus.

According to the present invention, an X-ray generation apparatus includes the electron beam apparatus.

According to the present invention, a scanning electron microscope includes the electron beam apparatus.

According to the present invention, it is possible to provide a small-sized high-resolution electron beam apparatus, and an X-ray generation apparatus and a scanning electron microscope each including the same.

### BRIEF DESCRIPTION OF THE DRAWINGS

FIG. 1 is a schematic configuration diagram illustrating one embodiment of an electron beam apparatus;

FIG. 2 is an enlarged diagram illustrating a convergence electrode of FIG. 1 and peripheries thereof;

FIG. 3 is an enlarged diagram illustrating a convergence electrode according to a comparative example and peripheries thereof;

FIG. 4 is a schematic configuration diagram illustrating a part of an electron beam apparatus according to a modified example;

FIG. 5 is a schematic configuration diagram illustrating a part of the electron beam apparatus according to the modified example; and

FIG. 6 is a schematic configuration diagram illustrating a part of the electron beam apparatus according to the modified example.

### DETAILED DESCRIPTION OF THE DRAWINGS

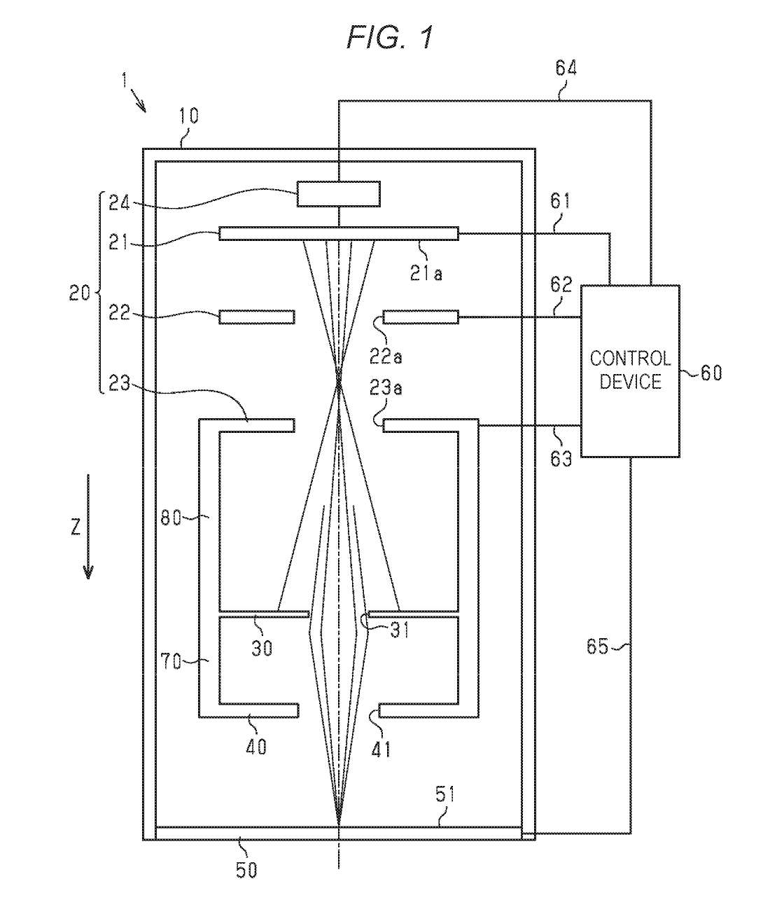

As illustrated in FIG. 1, an electron beam apparatus 1 includes a vacuum chamber 10 whose inside becomes a vacuum state by a vacuum pump (not shown in the drawing), an electron gun 20 which is placed in the vacuum chamber 10, an aperture member 30, and a convergence electrode 40. The electron beam apparatus 1 further includes a control device 60 which electrifies the electron gun 20, the aperture member 30, the convergence electrode 40, and a target object 50. The electron beam apparatus 1 causes an electron beam emitted from the electron gun 20 to pass through the aperture member 30, causes the electron beam to converge by the convergence electrode 40 after shielding peripheral parts of the electron beam, and causes a convergence surface 51, which is a surface of the target object 50, to be irradiated with the electron beam. The electron beam apparatus 1 is used for, for example, an X-ray generation apparatus and a scanning electron microscope. In a case where the electron beam apparatus 1 is used for the X-ray generation apparatus, the target object 50 is an X-ray generation target member. In a case where the electron beam apparatus 1 is used for the scanning electron microscope, the target object 50 is an inspection object.

The electron gun 20 includes a flat plate-shaped cathode 21, a ring-shaped control electrode 22, a ring-shaped anode 23, and an electrically-heating part 24. The cathode 21 is a generation source of electrons, and it is possible to use any one of a field emission type, a schottky type, and a thermionic electron emission type. In the embodiment, the thermionic electron emission type is used as the cathode 21. In the embodiment, the cathode 21 does not directly perform electric heating, and emits thermoelectrons by being heated up to prescribed temperature through electric heating of the electrically-heating part 24 which is disposed in the vicinity thereof. The cathode 21, the control electrode 22, and the anode 23 are arranged and disposed to be separated from each other in an optical axis direction Z which is a direction along an optical axis (a dashed line of FIG. 1) of the electron beam. The control electrode 22 is disposed between the cathode 21 and the anode 23 in the optical axis direction Z. A negative electric potential is applied to the control electrode 22 with respect to the cathode 21, and thus the quantity of electrons emitted from the cathode 21 is adjusted. The quantity of electrons emitted from the cathode 21 becomes large as an electric potential difference between the control electrode 22 and the cathode 21 becomes small.

The cathode 21 includes an emission surface 21a which is a planar surface capable of emitting the electrons. In the control electrode 22, a third hole 22a is formed through which the thermoelectrons emitted from the cathode 21 pass. A shape of the third hole 22a is, for example, a circle. In the anode 23, a first hole 23a is formed through which the electron beam passes. A shape of the first hole 23a is, for example, a circle. In a preferable example, an area of the emission surface 21a of the cathode 21 is wider than an opening area B of the third hole 22a formed in an electrode which is the nearest to the cathode 21, that is, the control electrode 22 in the embodiment. In a case where the shape of the third hole 22a is a circle and a radius of the third hole 22a is rb, a calculation formula used to acquire the opening area B of the third hole 22a is “B=π×rb2”.

The aperture member 30 is disposed on a side opposite to the control electrode 22 with respect to the anode 23. The convergence electrode 40 is disposed on a side opposite to the cathode 21 with respect to the aperture member 30. In other words, the aperture member 30 is disposed on a side of the cathode 21 rather than the convergence electrode 40. In the aperture member 30, an opening 31 is formed which shields some parts of the electron beam that passes through the anode 23. A shape of the opening 31 is, for example, a circle. It is possible to set a diameter of the opening 31 to a random value by taking resolution and light intensity into consideration. For example, the diameter of the opening 31 is 2 mm.

The convergence electrode 40 is a final-stage electrode which is disposed nearest to the target object 50 and which forms an electric field such that the electron beam converges on a convergence surface 51 of the target object 50. The convergence electrode 40 is, for example, a single-hole electrode in which a second hole 41 is formed in a flat plate. A shape of the second hole 41 is, for example, a circle. A diameter of the second hole 41 is larger than the diameter of the opening 31 of the aperture member 30. It is preferable that the diameter of the second hole 41 is determined to a size which does not shade the peripheral parts of the electron beam that passes through the opening 31 of the aperture member 30. In an example, the diameter of the second hole 41 is equal to the diameter of the first hole 23a of the anode 23 or is larger than the diameter of the first hole 23a. In another example, the diameter of the second hole 41 of the convergence electrode 40 is equal to the diameter of the third hole 22a of the control electrode 22 or is larger than the diameter of the third hole 22a. As illustrated in FIG. 1, the respective central axes of the third hole 22a of the control electrode 22, the first hole 23a of the anode 23, the opening 31 of the aperture member 30, and the second hole 41 of the convergence electrode 40 are the same.

The electron beam apparatus 1 includes a first electrically-conducting member 70 which causes the aperture member 30 and the convergence electrode 40 to be electrically conducted to each other in vacuum. The first electrically-conducting member 70 is, for example, a cylindrical member which connects the aperture member 30 to the convergence electrode 40. In addition, the electron beam apparatus 1 includes a second electrically-conducting member 80 which causes the anode 23 and the aperture member 30 to be electrically conducted to each other in vacuum. The second electrically-conducting member 80 is, for example, a cylindrical member which connects the anode 23 to the aperture member 30. In the embodiment, the anode 23, the aperture member 30, the convergence electrode 40, the first electrically-conducting member 70, and the second electrically-conducting member 80 are configured as one member which is formed of the same metal material.

The control device 60 is electrically connected to the cathode 21, the control electrode 22, the anode 23, the electrically-heating part 24, and the target object 50 through connection members 61, 62, 63, 64, and 65 such as a harness. The control device 60 is capable of changing electric potentials which are applied to the cathode 21, the control electrode 22, the anode 23, the electrically-heating part 24, and the target object 50 based on an operation of an operating unit (not shown in the drawing) provided in the electron beam apparatus 1. Hereinafter, an aspect of electrification of the cathode 21, the control electrode 22, the anode 23, the electrically-heating part 24, and the target object 50, which is performed by the control device 60, and an electron beam, which is irradiated to the convergence surface 51 of the target object 50 according to the aspect of the electrification, will be described.

The control device 60 is configured to heat the cathode 21 by electrifying the electrically-heating part 24 and to cause the control electrode 22 to apply a negative electric potential with respect to the electric potential of the cathode 21 and to apply a positive electric potential with respect to the anode 23. In addition, the control device 60 is configured to cause the convergence electrode 40 to apply the negative electric potential with respect to the electric potential of the target object 50, and to cause the electrons to be accelerated due to an electric potential difference between the target object 50 and the convergence electrode 40. Meanwhile, in the embodiment, as described above, the electric potential of the anode 23 and the electric potential of the convergence electrode 40 are the same. In addition, any one of the cathode 21, the control electrode 22, the anode 23, and the target object 50 may not be connected to the control device 60, that is, may be a ground electric potential.

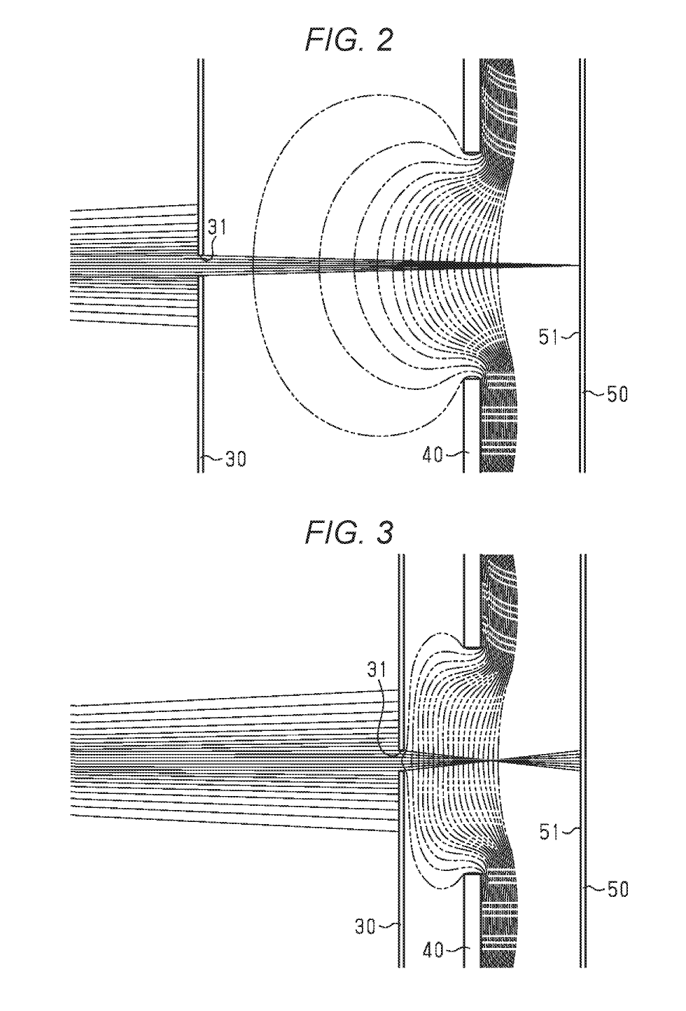

Due to the electric potential difference, the electrons emitted from the cathode 21 form the electron beam by being derived by the anode 23. In a case where the electric potential difference is generated between the control electrode 22 and the anode 23, electric fields are formed. A part of an equielectric potential surface between the control electrode 22 and the anode 23, which is resulting from the electric potential difference between the control electrode 22 and the anode 23, is swollen in a curved shape between the control electrode 22 and the cathode 21 via the third hole 22a of the control electrode 22, and thus an electro-static lens used to cause the electron beam to converge is formed. In addition, in a case where the electric potential difference between the convergence electrode 40 and the target object 50 is generated, electric fields are formed. As illustrated in FIG. 2, a part of the equielectric potential surface between the convergence electrode 40 and the target object 50, which is resulting from the electric potential difference between the convergence electrode 40 and the target object 50, is swollen in a curved shape between the convergence electrode 40 and the aperture member 30 via the second hole 41 of the convergence electrode 40, and thus the final-stage electro-static lens used to cause the electron beam to converge on the convergence surface 51 of the target object 50 is formed. Meanwhile, in the embodiment, as described above, the electric potentials of the anode 23, the aperture member 30, and the convergence electrode 40 are the same, and thus the electron beam approximately goes straight therebetween.

As illustrated in FIG. 1, the electron beam converges between the control electrode 22 and the anode 23, forms a crossover, and passes through the first hole 23a of the anode 23. Therefore, a beam diameter of the electron beam, which approximately goes straight from the anode 23 toward the convergence electrode 40, becomes wider as being closer to the convergence electrode 40.

In both configurations in which the aperture member 30 is provided like the electron beam apparatus 1 and in which the aperture member 30 is not provided unlike the electron beam apparatus 1, the electron beam converges by the final-stage electro-static lens which is formed by the convergence electrode 40, and the convergence surface 51 of the target object 50 is irradiated with the electron beam in a state in which the beam diameter of the electron beam becomes small. However, influence of spherical aberration on the electron beam, which converges due to the electric fields formed by the convergence electrode 40, is large as the beam diameter of the electron beam, which is acquired before reaching the electric field, is large, and thus it is not possible to acquire high resolution. In the electron beam apparatus 1 in which the aperture member 30 is provided, in a case where the electron beam formed by the anode 23 passes through the opening 31 of the aperture member 30, the peripheral parts of the electron beam are shaded by the aperture member 30, and only the central part of the electron beam passes through the opening 31. Therefore, the beam diameter of the electron beam is squeezed by the diameter of the opening 31, which is smaller than the beam diameter, before the electron beam passes through the opening 31. Therefore, the beam diameter of the electron beam, which reaches the final-stage electro-static lens formed by the convergence electrode 40, becomes small, with the result that the influence of the spherical aberration becomes small, and thus it is possible to acquire the high resolution.

Subsequently, relation between the anode 23, the aperture member 30, and the convergence electrode 40 will be described. Meanwhile, in the description below, distances between respective members, that is, the anode 23, the aperture member 30, and the convergence electrode 40 indicate the distances between the respective members in the optical axis direction Z.

In the embodiment, as described above, the electric potentials of the anode 23, the aperture member 30, and the convergence electrode 40 mutually become the same due to the first electrically-conducting member 70 and the second electrically-conducting member 80. Therefore, the anode 23 and the aperture member 30 may not be insulated for electric discharge prevention and, in addition, the aperture member 30 and the convergence electrode 40 may not be insulated for electric discharge prevention. That is, from a viewpoint of the electric discharge prevention, it is possible to randomly change the distance between the anode 23 and the aperture member 30 and the distance between the aperture member 30 and the convergence electrode 40, respectively, and it is possible to make the distances be shorter than an insulation distance which is necessary for the electric discharge prevention. In the embodiment, the distance between the anode 23 and the aperture member 30 is longer than the distance between the aperture member 30 and the convergence electrode 40, and the aperture member 30 shades the electron beam at a spot where the electron beam is further widened.

In contrast, the distance between the aperture member 30 and the convergence electrode 40 is restricted as below. As illustrated in FIG. 3, in a case where the distance between the aperture member 30 and the convergence electrode 40 is short, the respective equielectric potential surfaces of the electric fields, which leak from the second hole 41 of the convergence electrode 40 toward the aperture member 30, become straight line shapes which extend in a direction along a lower surface of the aperture member 30, and thus it is difficult that the electron beam converges. In addition, a part of the equielectric potential surfaces of the electric fields, which leak from the second hole 41 of the convergence electrode 40 toward the aperture member 30, is changed to a curve by the opening 31 of the aperture member 30. Therefore, the electron beam, which passes through the opening 31 of the aperture member 30, converges. A hole diameter of the opening 31 of the aperture member 30 may be designed by taking only improvement in the resolution according to reduction in the spherical aberration and balance of the quantity of electrons which reach the target object 50 into consideration. However, in a case where an operation as the lens is simultaneously performed, it is necessary to simultaneously satisfy a restriction on a lens property, such as a focal distance, and thus there is a possibility that sufficient resolution is not acquired as a result.

Here, setting is performed such that the distance between the aperture member 30 and the convergence electrode 40 is longer than a radius of the second hole 41 of the convergence electrode 40. More preferably, setting is performed such that the distance between the aperture member 30 and the convergence electrode 40 is equal to or longer than the diameter of the second hole 41 of the convergence electrode 40. In the embodiment, the distance between the aperture member 30 and the convergence electrode 40 is longer than the diameter of the second hole 41 of the convergence electrode 40. Therefore, as illustrated in FIG. 2, it is difficult for the final-stage electro-static lens, which is formed by a part of the equielectric potential surfaces of the electric fields that leak from the second hole 41 of the convergence electrode 40 toward the aperture member 30, to be formed in the opening 31 of the aperture member 30, and thus it is possible to ignore the operation of the lens in the opening 31. Therefore, it is possible to design the hole diameter of the opening 31 of the aperture member 30 by taking only the resolution and light quantity into consideration, and thus it is easy to acquire desired electron gun performance.

According to the electron beam apparatus 1 of the embodiment, the following advantages are acquired.

(1) Since the convergence electrode 40 is one single-hole electrode, it is possible to reduce the size of the convergence electrode 40 in the optical axis direction Z, compared to a case where it is assumed that the convergence electrode 40 includes, for example, a plurality of single-hole electrodes like an einzel lens. Therefore, it is possible to reduce the size of the electron beam apparatus 1. In addition, since only one convergence electrode 40 exists as an electrode used to cause the electron beam to converge between the anode 23 and the target object 50 in the optical axis direction Z, it is possible to further reduce the size of the electron beam apparatus 1.

In addition, the beam diameter of the electron beam emitted from the anode 23 toward the aperture member 30 becomes wider as being closer to the aperture member 30. Furthermore, after only the central part of the electron beam passes through the opening 31 of the aperture member 30, the electron beam converges by the convergence electrode 40. Therefore, it is possible to reduce the influence of the spherical aberration. As described above, since the aperture member 30 is provided, it is possible to acquire the high resolution even in a case where the number of electrodes, which exist between the aperture member 30 and the convergence surface 51 of the target object 50, is one. Therefore, it is possible to reduce the size of the electron beam apparatus 1 with high resolution.

In addition, in a case where it is assumed that the aperture member 30 is disposed on a side of the target object 50 rather than the convergence electrode 40 and an electric potential, which is the same as that of the target object 50, is applied to the aperture member 30, it is necessary to shade the peripheral parts of the electron beam, which converges by the convergence electrode 40, by the aperture member 30 in order to reduce the influence of the spherical aberration. Therefore, it is necessary to cause the diameter of the opening 31 to be smaller than the converging electron beam and to dispose the opening 31 of the aperture member 30 at a central position of the electron beam, and processing accuracy and positional accuracy should be increased. In addition, in addition thereto, there is a possibility that addition of a component, such as provision of a deflector for adjusting a position of the electron beam, is necessary in order to cause the electron beam to pass through the opening 31 of the aperture member 30.

In the embodiment, an electron beam, which is acquired immediately before converging by the convergence electrode 40, that is, an electron beam, which converges by the electron gun 20 once and then the diameter thereof is enlarged, passes through the opening 31 of the aperture member 30. Therefore, it is possible to shade the electron beam as much as a desired quantity even in a case where the processing accuracy and the positional accuracy of the opening 31 of the aperture member 30 are low. Therefore, it is possible to easily construct the electron beam apparatus 1. In addition, it is not necessary to provide the deflector and it is possible to simplify a configuration of the electron beam apparatus 1.

(2) In a case where the same electric potential is applied to the aperture member 30 and the convergence electrode 40, it is not necessary to provide an insulation distance used to prevent electric discharge between the convergence electrode 40 and the aperture member 30. Therefore, it is possible to cause the distance between the convergence electrode 40 and the aperture member 30 to be short in the optical axis direction Z. Therefore, it is possible to reduce the size of the electron beam apparatus 1.

(3) In a case where the aperture member 30 and the convergence electrode 40 are electrically conducted to each other in vacuum by the first electrically-conducting member 70, the electric potential of the convergence electrode 40 and the electric potential of the aperture member 30 become the same even though the number of wires, which are used to electrically connect the control device 60 to the convergence electrode 40 and the aperture member 30, is reduced. Therefore, it is possible to simplify the configuration of the electron beam apparatus 1.

(4) In a case where the distance between the aperture member 30 and the convergence electrode 40 is longer than the radius of the second hole 41 of the convergence electrode 40, it is possible to ignore the operation of the electro-static lens due to the aperture member 30. Therefore, it is possible to design the hole diameter of the opening 31 of the aperture member 30 by taking only the resolution and the light quantity into consideration.

(5) In a case where the same electric potential is applied to the anode 23 and the aperture member 30, it is not necessary to provide the insulation distance used to prevent electric discharge between the anode 23 and the aperture member 30. Therefore, it is possible to cause the distance between the anode 23 and the aperture member 30 to be short in the optical axis direction Z. Therefore, it is possible to reduce the size of the electron beam apparatus 1.

(6) In a case where the anode 23 and the aperture member 30 are electrically conducted to each other in vacuum by the second electrically-conducting member 80, the electric potential of the anode 23 and the electric potential of the aperture member 30 become the same even though the number of wires, which are used to electrically connect the control device 60 to the anode 23 and the aperture member 30, is reduced. Therefore, it is possible to simplify the configuration of the electron beam apparatus 1.

Specifically, since the anode 23, the aperture member 30, and the convergence electrode 40 are electrically conducted to each other, it is possible to electrically connect the control device 60 to the anode 23, the aperture member 30, and the convergence electrode 40 through one wire. Therefore, it is possible to further simplify the configuration of the electron beam apparatus 1.

(7) It is desired that the cathode 21 is the thermionic electron emission type. A method for applying heat to the cathode 21 may be a directly-heated type in which electric heating is directly performed or may be an indirectly-heated type in which the electrically-heating part 24 that heats the cathode 21 is further included. In both cases, the cathode 21 is the thermionic electron emission type, and thus a degree of vacuum in the vacuum chamber 10 may be low compared to, for example, a case where the cathode 21 is an electric field emission type. Therefore, it is possible to reduce a size of the vacuum pump 3 used to vacuate the inside of the vacuum chamber 10.

(8) In addition, it is desired that a shape of the cathode 21 is a plane. In a case where an area of the emission surface 21a of the cathode 21 is caused to be larger than an electrode which is the nearest to the cathode 21, that is, the opening area of the third hole 22a of the control electrode 22, even though the cathode 21 is deviated from a position, which is preset with respect to the control electrode 22, in a direction which is orthogonal to the optical axis direction Z, it is possible to cause the electrons to pass through the third hole 22a in a state in which an optical axis of the electron beam emitted from the cathode 21 coincides with a central axis of the third hole 22a of the control electrode 22. As above, it is not necessary to perform high-precision adjustment on the position of the cathode 21 with respect to the control electrode 22, and thus it is possible to easily construct the electron beam apparatus 1.

(9) In addition, from a viewpoint of long term stabilities of a lifetime and an optical property, it is desired that the cathode 21 is an impregnated planar thermal cathode. For example, in a case where a closed-type electron gun which is maintenance free is applied as the electron gun 20, a replacement frequency of the closed-type electron gun is low, and thus it is possible to reduce maintenance costs of the electron beam apparatus 1. Meanwhile, the closed-type electron gun has a configuration in which the whole electron gun is exchanged in a case where it is necessary to exchange a partial component of the electron gun due to failure or the like.

### Modified Example

The description related to the embodiment is an example of a form which may be applied to the electron beam apparatus, the X-ray generation apparatus, and the scanning electron microscope according to the present invention, and a restriction on the form is not intended. For example, a modified example of the embodiment which will be illustrated below and a form, in which at least two modified examples that do not conflict with each other are combined, may be applied to the electron beam apparatus, the X-ray generation apparatus, and the scanning electron microscope according to the present invention.

In the embodiment, the resolution is improved in such a way that the crossover of the electron beam is formed by the control electrode 22 of the electron gun 20. However, the configuration of the electron gun 20 is not limited thereto. The control electrode 22 may be omitted from the electron gun 20. Therefore, it is possible to reduce the size of the electron gun 20.

In the embodiment, the anode 23, the aperture member 30, and the convergence electrode 40 are electrically conducted to each other. However, an electrical configuration of the anode 23, the aperture member 30, and the convergence electrode 40 is not limited thereto, and can be changed as in subsequent (A)˜(H).

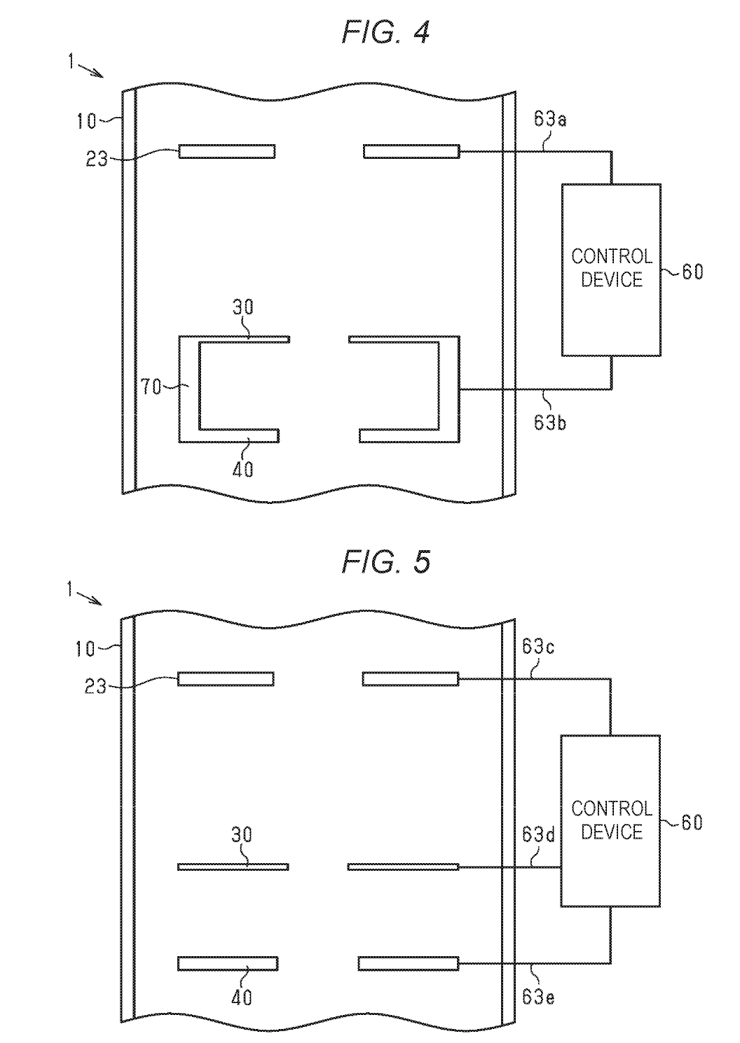

(A) As illustrated in FIG. 4, the aperture member 30, the convergence electrode 40, and the first electrically-conducting member 70 are integrally formed, and the anode 23 is separately formed from the aperture member 30, the convergence electrode 40, and the first electrically-conducting member 70. That is, the second electrically-conducting member 80 is omitted. The control device 60 is electrically connected to the anode 23 by, for example, a connection member 63a, such as harness, and is electrically connected to the aperture member 30, the convergence electrode 40, and the first electrically-conducting member 70 by a connection member 63b. The control device 60 electrifies the anode 23, the aperture member 30, and the convergence electrode 40 such that the electric potential of the anode 23, the electric potential of the aperture member 30, and the electric potential of the convergence electrode 40 become the same. According to the configuration, the same advantages as in (1)˜(5), (7), (8), and (9) of the embodiment are acquired.

(B) As illustrated in FIG. 5, the anode 23, the aperture member 30, and the convergence electrode 40 are individually formed, and are not electrically conducted to each other. That is, the first electrically-conducting member 70 and the second electrically-conducting member 80 are omitted. The control device 60 is electrically connected to the anode 23, the aperture member 30, and the convergence electrode 40, respectively, via, for example, connection members 63c, 63d, and 63e such as the harness. The control device 60 electrifies the anode 23, the aperture member 30, and the convergence electrode 40, respectively, such that the electric potential of the anode 23, the electric potential of the aperture member 30, and the electric potential of the convergence electrode 40 mutually become the same. According to the configuration, the same advantages as in (1), (2), (4), (5), (7), (8), and (9) of the embodiment are acquired.

(C) In the modified example of FIG. 4, the control device 60 generates an electric potential difference between the aperture member 30 and the anode 23 and an electric potential difference between the convergence electrode 40 and the anode 23 such that the electric potentials of the aperture member 30 and the convergence electrode 40 and the electric potential of the anode 23 become different from each other. According to the configuration, the same advantages as in (1)˜(4), (7), (8), and (9) of the embodiment are acquired.

(D) In the modified example of FIG. 5, the control device 60 electrifies any one of the aperture member 30, the convergence electrode 40, and the first electrically-conducting member 70 such that the electric potential of the aperture member 30 and the electric potential of the convergence electrode 40 become the same, and generates an electric potential difference between the anode 23 and the aperture member 30 and an electric potential difference between the anode 23 and the convergence electrode 40 such that the electric potential of the aperture member 30 and the electric potential of the anode 23 become different from each other. According to the configuration, the same advantages as in (1), (2), (4), (7), (8), and (9) of the embodiment are acquired.

(E) In the modified example of FIG. 5, the control device 60 electrifies the anode 23 and the aperture member 30, respectively, such that the electric potential of the anode 23 and the electric potential of the aperture member 30 become the same, and generates the electric potential difference between the aperture member 30 and the convergence electrode 40 such that the electric potential of the aperture member 30 and the electric potential of the convergence electrode 40 become different from each other. According to the configuration, the same advantages as in (1), (4), (5), (7), (8), and (9) of the embodiment are acquired.

(F) In the modified example of FIG. 5, the control device 60 generates the electric potential differences between the anode 23, the aperture member 30, and the convergence electrode 40 such that electric potentials of the anode 23, the aperture member 30, and the convergence electrode 40 are different from each other. According to the configuration, the same advantages as in (1), (4), (7), (8), and (9) of the embodiment are acquired.

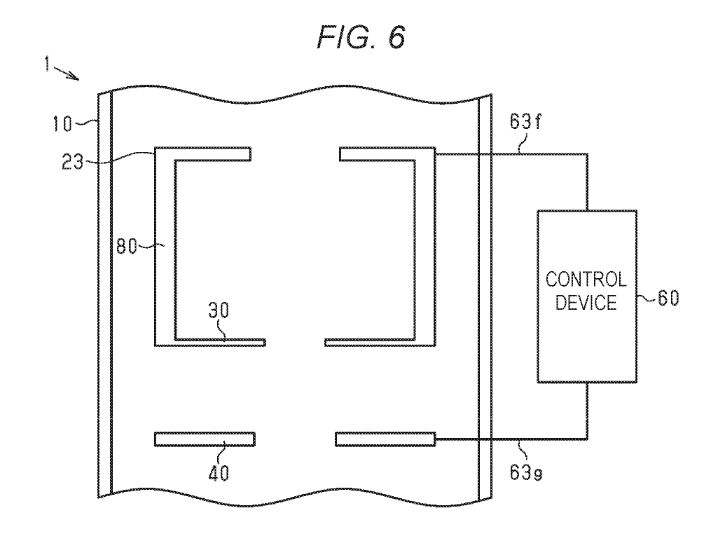

(G) As illustrated in FIG. 6, the anode 23 and the aperture member 30 are integrally formed, and the convergence electrode 40 is formed separately from the anode 23 and the aperture member 30. That is, the first electrically-conducting member 70 is omitted. The control device 60 is electrically connected to the anode 23 and the aperture member 30 by, for example, a connection member 63f, such as harness, and is electrically connected to the convergence electrode 40 by the connection member 63g. The control device 60 electrifies the anode 23, the aperture member 30, and the convergence electrode 40 such that the electric potential of the anode 23, the electric potential of the aperture member 30, and the electric potential of the convergence electrode 40 become the same. According to the configuration, the same advantages as in (1), (2), and (4)˜(9) of the embodiment are acquired.

(H) In the modified example of FIG. 6, the control device 60 electrifies any one of the anode 23 and the aperture member 30 such that the electric potentials of the anode 23 and the aperture member 30 become the same, and generates the electric potential difference between the anode 23 and the aperture member 30 and the electric potential difference between the anode 23 and the convergence electrode 40 such that the electric potentials of the aperture member 30 and the convergence electrode 40 are different from each other. According to the configuration, the same advantages as in (1) and (4)˜(9) of the embodiment are acquired.

1. An electron beam apparatus comprising:
a cathode configured to emit electrons;
an anode that is an electrode which forms an electric field such that an electron beam is formed by the electrons emitted from the cathode, and that is formed with a first hole through which the electron beam passes;
an aperture member formed with an opening that shields a part of the electron beam which passes through the anode; and
a final-stage electron lens that is an electrode which forms an electric field such that the electron beam which passes through the opening converges, and that is configured to include one single-hole electrode formed with a second hole through which the electron beam passes.

2. The electron beam apparatus according to claim 1, wherein an electric potential of the aperture member is the same as an electric potential of the single-hole electrode.

3. The electron beam apparatus according to claim 2, further comprising:
a first electrically-conducting member in which the aperture member and the single-hole electrode are electrically conducted to each other in vacuum, and which is different from a wire configured to apply the electric potential.

4. The electron beam apparatus according to claim 3, wherein an electric potential of the anode is the same as the electric potential of the aperture member.

5. The electron beam apparatus according to claim 4, further comprising:
a second electrically-conducting member in which the anode is electrically conducted to the aperture member in vacuum, and which is different from the wire configured to apply the electric potential.

6. The electron beam apparatus according to claim 1, wherein a distance between the aperture member and the single-hole electrode in a direction along an optical axis of the electron beam is longer than a radius of the second hole.

7. The electron beam apparatus according to claim 1, wherein the cathode includes an emission surface which is a planar surface capable of emitting the electrons, and an area of the emission surface is larger than an opening area of the first hole.

8. The electron beam apparatus according to claim 1, wherein the cathode is a thermionic electron emission type.

9. An X-ray generation apparatus comprising the electron beam apparatus according to claim 1.

10. A scanning electron microscope comprising the electron beam apparatus according to claim 1.
